(19) United States
(12) Patent Application Publication
(10) Pub. No.: US 2009/0135347 A1
(43) Pub. Date: May 28, 2009

(54) DISPLAY DEVICE AND MANUFACTURING METHOD THEREOF

(76) Inventors: Woo-Seok Jeon, Seongnam-si (KR); Jang-Soo Kim, Yongin-si (KR); Young-Wook Lee, Suwon-si (KR); Jung-In Park, Suwon-si (KR); Hi-Kuk Lee, Yongin-si (KR); Shi-Yul Kim, Yongin-si (KR); Jin-Seuk Kim, Daedeok-gu (KR); Jae-Hyoung Youn, Seoul (KR); Ki-Won Kim, Suwon-si (KR); Su-Hyoung Kang, Bucheon-si (KR)

Correspondence Address: Haynes and Boone, LLP;IP Section, 2323 Victory Avenue, SUITE 700, Dallas, TX, 75219, US

(21) Appl. No.: 12/184,842

(22) Filed: Aug. 1, 2008

(30) Foreign Application Priority Data
Nov. 28, 2007 (KR) 10-2007-0122239

(51) Int. Cl. G02F 1/1335; G03F 7/20; B05D 5/06

(52) U.S. Cl. 349/106; 430/319; 430/313; 427/58

(57) ABSTRACT

A manufacturing method of a display device, wherein the manufacturing method for an embodiment includes: forming color filters in a plurality of pixel regions; forming a conductive layer on the color filters; and separating the conductive layer in each of the pixel regions through a photolithography process and forming a pixel electrode; wherein a groove is formed between the adjacent color filters having different colors at boundaries between the pixel regions; and wherein the photolithography process uses a negative photoresist material.

### CROSS-REFERENCE TO RELATED APPLICATION

This application claims priority to and benefit from Korean Patent Application No. 10-2007-0122239, filed on Nov. 28, 2007 in the Korean Intellectual Property Office, the disclosure of which is incorporated herein by reference in its entirety.

### BACKGROUND

1. Technical Field

Apparatuses and methods consistent with embodiments of the present invention generally relate to a display device which prevents errors and improves quality, and a manufacturing method thereof.

2. Description of the Related Art

There are several kinds of display devices. With the rapid progress of semiconductor technology, a display device that includes a liquid crystal display (LCD) panel has become popular since it is small and light.

Generally, a liquid crystal display device includes a circuit substrate formed with a thin film transistor and a pixel electrode thereon, and a counter substrate which faces the circuit substrate and forms a color filter thereon.

To simplify manufacturing processes and raise productivity, a COA (color filter on array) display device which forms a color filter on the circuit substrate instead of on the counter substrate has been developed.

The COA display device generally forms a conductive layer pattern such as a pixel electrode on a color filter through photolithography.

The color filter is relatively thicker than other layers. Also, the color filter is heavily curved at a boundary with other color filters of adjacent pixels. Thus, the thickness of the color filter is irregular and non-uniform.

Accordingly, when the photolithography is performed on a conductive layer disposed on the color filter, etching errors may be generated. That is, the conductive layer pattern which is formed by the photolithography is not precise and unnecessary (undesired) short-circuits may likely occur.

As the color filter is relatively thick, the display device has a region in which a space between the circuit substrate and the counter substrate is very narrow. The substrates having the narrow space therebetween may contact each other while being coupled with each other. When the display apparatus having the unnecessarily contacted region receives external vibration or shock, the unnecessarily contacted region with the substrates may be detached from each other. Then, room is created in a liquid crystal layer interposed between the circuit substrate and the counter substrate and errors occur due to a lack of liquid crystals.

### SUMMARY

Accordingly, one or more embodiments of the present invention provide a display device which may prevent errors such as a short-circuit or a lack of liquid crystals, and a manufacturing method thereof.

The foregoing and/or other embodiments of the present invention may be achieved by providing a manufacturing method of a display device, the manufacturing method comprising: forming color filters in a plurality of pixel regions; forming a conductive layer on the color filters; and separating the conductive layer in each of the pixel regions through a photolithography process and forming a pixel electrode; a groove being formed between the adjacent color filters having different colors at boundaries between the pixel regions; and the photolithography process using a negative photoresist material.

Embodiments of the photolithography process may comprise: applying a negative photoresist material to the conductive layer; exposing the negative photoresist material with a mask; forming a photoresist layer pattern by developing the exposed negative photoresist material; and forming a pixel electrode by etching the conductive layer through the photoresist layer pattern; wherein the negative photoresist material applied to the groove between the adjacent color filters is removed through the developing process.

Embodiments of the manufacturing method may further comprise forming a metal wire below the groove, wherein a width of the groove is narrower than a width of the metal wire.

The foregoing and/or other embodiments of the present invention can be achieved by providing a manufacturing method of a display device, the manufacturing method comprising: forming color filters in a plurality of pixel regions; forming a photoresist layer pattern on the color filters through a photo-developing process; forming a conductive layer on the photoresist layer pattern; and forming a pixel electrode with the conductive layer by removing the photoresist layer pattern; a groove being formed between the adjacent color filters having different colors at boundaries between the pixel regions.

Embodiments of the photo-developing process may comprise: applying a photoresist material to the color filters; exposing the photoresist material with a mask; forming a photoresist layer pattern by developing the exposed photoresist material; and the photoresist layer pattern comprising a photoresist layer formed on the groove between the adjacent color filters.

The conductive layer which may be formed on the photoresist layer of the photoresist layer pattern is removed together with the photoresist layer in the operation of removing the photoresist layer pattern. The photoresist material may comprise one of a positive photoresist material and a negative photoresist material.

The foregoing and/or other embodiments of the present invention can be achieved by providing a display device which has a plurality of pixels and displays an image, the display device comprising: a first substrate member; a second substrate member which faces the first substrate member; a color filter which is formed in each of the pixels on the first substrate member; a metal wire which is disposed between the first substrate member and the color filter; and a pixel electrode which is disposed between the color filter and the second substrate member; a groove being formed between the adjacent color filters having different colors at boundaries between the pixels; a part of the metal wire being disposed below the groove between the adjacent color filters having different colors; and a width of the groove being narrower than a width of the metal wire. An angle of a lateral inclination of the groove formed between the adjacent color filters may be approximately 40° or more.

The foregoing and/or other embodiments of the present invention can be achieved by providing a display device which is divided into a display region having a plurality of pixels and a non-display region surrounding the display region, the display device comprising: a first substrate member; a color filter which is formed in each of the pixels on the first substrate member; a second substrate member which faces the first substrate member; a light blocking member which is formed at boundaries between the pixels on a surface of the second substrate member facing the first substrate member; and a liquid crystal layer which is interposed between the first substrate member and the second substrate member; the adjacent color filters having different colors at boundaries between the pixels and overlapping each other to form an overlapping part which is relatively higher than others; and the light blocking member corresponding to the overlapping part and having a thickness of approximately 0.7 μm or less.

The color filters and the light blocking member may be further formed on the non-display region. The display device may further comprise a sealant which is disposed along a circumference of the first and second substrate members in the non-display region. The color filter which may be formed in the non-display region may have a blue color.

The display device may further comprise a thin film transistor which is formed on the first substrate member, wherein the light blocking member is further formed on a place corresponding to the thin film transistor; and the display device further comprises a substrate spacing member which is formed on the light blocking member and maintains a space between the first and second substrate members. A minimum thickness of the liquid crystal layer may be approximately 1 μm or more.

The foregoing and/or other embodiments of the present invention can be achieved by providing a manufacturing method of a display device, the manufacturing method comprising: forming a color filter which has an overlapping part in a plurality of pixel regions; and forming a boundary part having a thinner thickness than that of the overlapping part by grinding the overlapping part of the color filters; the overlapping part being formed by overlapping the adjacent color filters having different colors at boundaries between the pixel regions and being higher than others.

The color filters may be formed on the first substrate member. An embodiment of the manufacturing method further comprises: disposing a second substrate member to face the first substrate member; and interposing a liquid crystal layer between the first and second substrate members, a minimum thickness of the liquid crystal layer being approximately 1 μm or more.

### BRIEF DESCRIPTION OF THE DRAWINGS

The above and/or other embodiments of the present invention will become apparent and more readily appreciated from the following description of the exemplary embodiments, taken in conjunction with the accompanying drawings, in which:

FIG. 1 is an arrangement view of a display device according to a first exemplary embodiment of the present invention;

FIG. 2 is a sectional view of main parts of the display device in FIG. 1;

FIG. 3 is a sectional view of main parts of a display device according to a second exemplary embodiment of the present invention;

FIG. 4 is a sectional view of main parts of a display device according to a third exemplary embodiment of the present invention;

FIGS. 5 to 10 are sectional views to sequentially describe a manufacturing method of a display device according to a fourth exemplary embodiment of the present invention; and

FIGS. 11 to 14 are sectional views to sequentially describe a manufacturing method of a display device according to a fifth exemplary embodiment of the present invention.

### DETAILED DESCRIPTION

Reference will now be made in detail to the embodiments of the present invention, examples of which are illustrated in the accompanying drawings, wherein like reference numerals refer to like elements throughout.

Also, the drawings may illustrate an enlarged thickness of layers and regions to be clearly represented. The term “on” means that a new layer, film, region or panel may be interposed or not interposed between two layers, films, regions or panels, and the term “directly on” means that two layers, films, regions or panels are in contact with each other.

The drawings illustrate as an example a display panel for one or more embodiments which employs an amorphous silicon (a-Si) thin film transistor (TFT) formed by a five mask process. The present invention is not limited thereto, and may be embodied by various configurations and processes.

To clarify the present invention, unrelated descriptions are avoided.

### Exemplary Embodiment 1

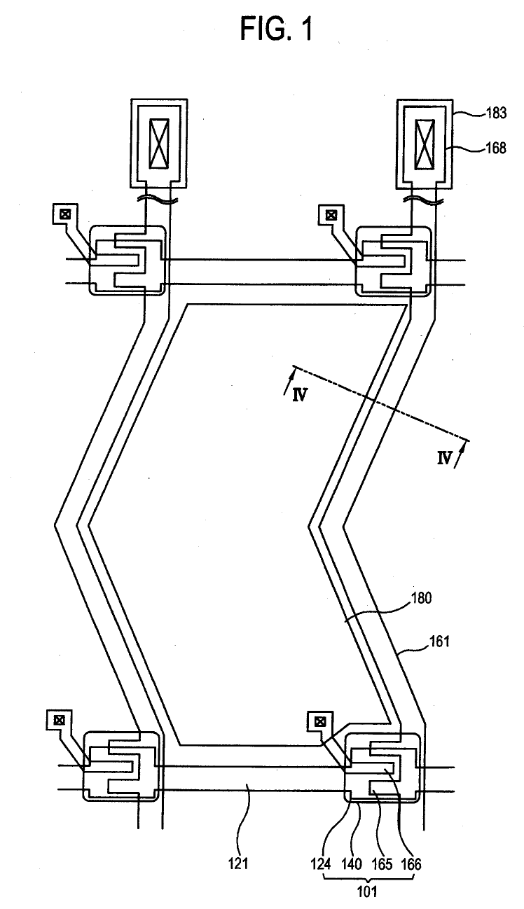

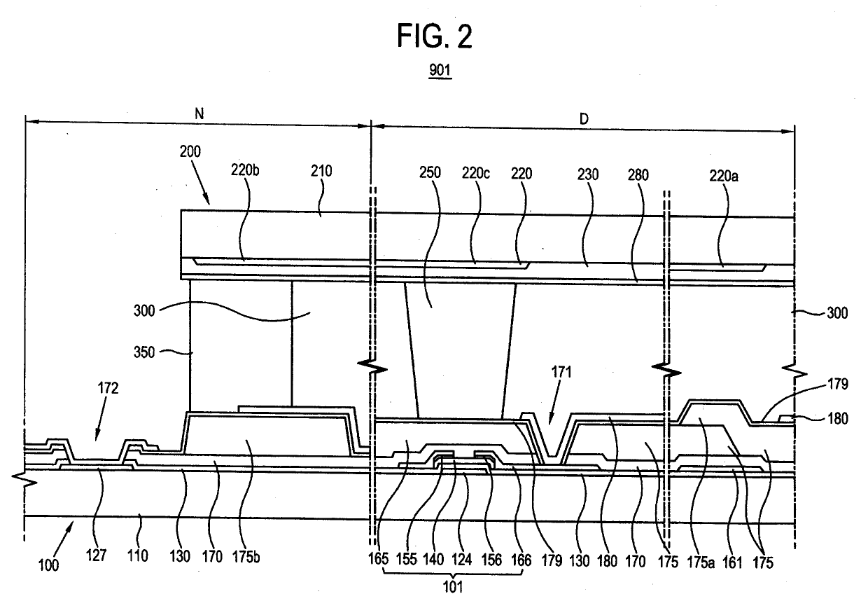

Referring to FIGS. 1 and 2, a display device according to a first exemplary embodiment of the present invention will be described. FIG. 1 is an arrangement view of a display apparatus 901 (also shown in FIG. 2) according to the first exemplary embodiment of the present invention. FIG. 2 is an enlarged view of the display device 901 according to the first exemplary embodiment of the present invention, which is divided into a display region D and a non-display region N.

As shown therein, the display device 901 includes a first display panel 100, a second display panel 200 and a liquid crystal layer 300. The display device 901 is divided into a display region D having a plurality of pixels, and a non-display region N surrounding the display region D. Here, the pixel refers to a smallest unit of displaying an image.

Hereinafter, the configuration of the first display panel 100 will be described.

A first substrate member 110 includes a transparent material such as glass, quartz, ceramic or plastic.

Gate wires 121 (also referred to as “gate line”) and 124 (also referred to as “gate electrodes”) are formed on the first substrate member 110. The gate wires 121 and 124 respectively include a gate line 121 and a plurality of gate electrodes 124 branched from the gate line 121. The gate wires 121 and 124 may further include a storage electrode line (not shown). The gate wires 121 and 124 further include a gate pad 127 which is formed in the non-display region N and connected to an end part of the gate line 121.

The gate wires 121 and 124 may include metal such as Al, Ag, Cr, Ti, Ta, Mo and Cu or an alloy thereof. FIG. 2 illustrates the gate wires 121 and 124 as a single layer. Alternatively, the gate wires 121 and 124 may include multiple layers having metal layers such as Cr, Mo, Ti, Ta or an alloy thereof which have good physical and chemical properties, and metal layers such as Al series or Ag series which have small specific resistance. Otherwise, the gate wires 121 and 124 may include various metals or conductive materials, or multiple layers thereof which can be patterned under equivalent etching conditions.

A gate insulating layer 130 which includes silicon nitride (SiNx) is formed on the gate wires 121 and 124.

Data wires 161 (also referred to as “data line”), 165 (also referred to as “source electrode”) and 166 (also referred to as “drain electrodes”) are formed on the gate insulating layer 130. The data wires 161, 165 and 166 include respectively a data line 161 intersecting the gate line 121, a source electrode 165 branched from the data line 161, and drain electrodes 166 spaced from the source electrode 165. The data wires 161, 165 and 166 further include a data pad 168 which is formed on the non-display region N and connected to an end part of the data line 161.

The data wires 161, 165 and 166 may include a conductive material such as chrome, molybdenum, aluminum, copper or an alloy thereof. The data wires 161, 165 and 166 may include a single or multiple layers.

A semiconductor layer 140 is formed between the gate insulating layer 130 of the gate electrodes 124 and the source electrode 165 and the drain electrodes 166. At least a part of the semiconductor layer 140 overlaps the gate electrodes 124, the source electrode 165 and the drain electrodes 166. Here, the gate electrodes 124, the source electrodes 165 and the drain electrodes 166 serve as three electrodes of a thin film transistor 101. The semiconductor layer 140 formed between the source electrodes 165 and the drain electrodes 166 is a channel region of the thin film transistor 101.

Ohmic contact members 155 and 156 are formed between the semiconductor layer 140, and the source electrodes 165 and the drain electrodes 166 to reduce contact resistance therebetween. The ohmic contact members 155 and 156 include silicide or amorphous silicon highly doped with an n-type dopant.

A passivation layer 170 is formed on the data wires 161, 165 and 166. The passivation layer 170 includes an insulating material with a low permittivity such as a-Si:C:O and a-Si:O:F formed by a plasma enhanced chemical vapor deposition (PECVD), an inorganic insulating material such as silicon nitride and silicon oxide or an organic insulating material.

A color filter 175 having the three primary colors is sequentially provided on the passivation layer 170. The color of the color filter 175 is not limited to the three primary colors, and may vary including at least one color. The color filter 175 assigns color to light which passes through the display device 901.

The color filter 175 is formed in each pixel in the display region D. The color filters 175 have different colors and are adjacent to each other at boundaries between pixels. The color filters 175 overlap each other at the boundaries between the pixels and form an overlapping part 175a which is higher than others. At least a part of the gate line 121 or of the data line 161 overlaps the overlapping part 175a.

The color filters 175 are further formed on the non-display region N. A color filter 175b which is formed on the non-display region N may have a blue color, but is not limited thereto. Alternatively, the color filter 175b may be removed from the non-display region N, or may have other colors than the blue color in the non-display region N.

The color filters 175 are formed on the passivation layer 170, but not limited thereto. Alternatively, the color filters 175 may be formed between the passivation layer 170 and the data wires 161, 165 and 166.

A capping layer 179 is formed on the color filters 175. The capping layer 179 caps organic layers, for example, including the color filters 175. The capping layer 179 can be removed as necessary. The capping layer 179 may include various materials similar to that of the passivation layer 170.

A pixel electrode 180 is formed on the capping layer 179. The pixel electrode 180 includes a transparent conductive material such as indium tin oxide (ITO) or indium zinc oxide (IZO).

The passivation layer 170, the color filters 175 and the capping layer 179 have a contact hole 171 to expose at least a part of the drain electrodes 166 therethrough. The pixel electrode 180 and the drain electrodes 166 are electrically connected to each other through the contact hole 171. At least one of the gate insulating layer 130 and the passivation layer 170 includes an exposing hole 172 to expose the gate pad 127 and the data pad 168. A contact member 183, which is formed by the same material and process as the pixel electrode 180, contacts the gate pad 127 and the data pad 168 through the exposing hole 172.

Hereinafter, the configuration of the second display panel 200 will be described.

A second substrate member 210 faces the first substrate member 110. Like the first substrate member 110, the second substrate member 210 includes a transparent material such as glass, quartz, ceramic or plastic.

A light blocking member 220 is formed on the second substrate member 210. More specifically, the light blocking member 220 is formed along the boundaries between the pixels on a surface of the second substrate member 210 facing the first substrate member 110. That is, the light blocking member 220 corresponds to the overlapping part 175a of the color filters 175 in the first display panel 100. A light blocking member 220a which is disposed at the boundaries between the pixels blocks light from leaking unnecessarily between the pixels.

The light blocking member 220 is further formed on the non-display region N. That is, the light blocking member 220 formed on the non-display region N corresponds to the color filter 175b formed in the non-display region N of the first display panel 100. The light blocking member 220b formed on the non-display region N blocks external, intense light from being emitted to the first display panel 100, the second display panel 200 and the liquid crystal layer 300.

The light blocking member 220 is further formed in a place corresponding to the thin film transistor 101 of the first display panel 100. A light blocking member 220c which corresponds to the thin film transistor 101 prevents light from being supplied to the channel region of the thin film transistor 101 and prevents errors such as a light leaking current from being generated.

The light blocking member 220 includes a metal material. The light blocking member 220 may include a photoresist organic material added with a black pigment to block light. The black pigment may include carbon black.

The light blocking member 220 may have a thickness of approximately 0.7 μm or less. Particularly, the light blocking member 220a which corresponds to the overlapping part 175a of the color filters 175 in the first display panel 100 should be approximately 0.7 μm or less in thickness. Meanwhile, the light blocking members 220b and 220c which are disposed in other places may be approximately 0.7 μm or more in thickness. The thicker the light blocking member 220 is, the more stably it blocks light. That is, given the light blocking effects only, a thicker light blocking member 220 is better. However, when the light blocking member 220 is too thick, a space between the first and second display panels 100 and 200 becomes too narrow due to the thickness of the light blocking member 220. Thus, the thickness of the light blocking member 200 may be approximately 0.7 μm or less to maintain a proper space between the first and second display panels 100 and 200. This is a thickness that the light blocking member 220 may have, in consideration of the thickness of other layers of the display device 901 so that the liquid crystal layer 300 interposed between the first and second display panels 100 and 200 maintains a minimum thickness of approximately 1 μm or more.

A color filter 175b which is formed in the non-display region N helps the light blocking member 220b effectively block external, intense light, even when the light blocking member 220b formed on the non-display region N has a thickness of 0.7 μm or less.

An overcoat layer 230 is formed on the light blocking member 220. The overcoat layer 230 provides a planar surface and protects the light blocking member 220. The overcoat layer 230 according to an embodiment of the present invention can be omitted.

A common electrode 280 is formed on the overcoat layer 230 to form an electric field together with the pixel electrode 180. The common electrode 280 includes a transparent conductive material such as ITO or IZO.

The liquid crystal layer 300 is interposed between the first and second display panels 100 and 200. The minimum thickness of the liquid crystal layer 300 may be 1 μm or more. When the first and second display panels 100 and 200 are spaced from each other as much as at least 1 μm, the first and second display panels 100 and 200 may not contact each other unnecessarily, and errors due to a lack of liquid crystals may be prevented efficiently.

The space between the first and second display panels 100 and 200 is the narrowest in an area where the overlapping part 175a of the first display panel 100 and the light blocking member 220 of the second display panel 200 are disposed. The overlapping part 175a of the first display panel 100 is higher than others and formed by overlapping the color filters 175 having different colors at boundaries between the pixels, and the light blocking member 220 of the second display panel 200 corresponds to the overlapping part 175a. In that area, the first and second display panels 100 and 200 may be spaced from each other at least 1 μm or more.

The display device 901 may further include a substrate spacing member 250 which is formed on the light blocking member 220 and stably maintains a space between the first and second substrate members 110 and 210, i.e., a space between the first and second display panels 100 and 200.

The display device 901 may further include a sealant 350, which is disposed between the light blocking member 220 and the color filters 175, formed in the non-display region N and which seals the first and second display panels 100 and 200.

With the foregoing configuration, the display device 901 according to the first exemplary embodiment of the present invention may prevent errors such as a short-circuit or a lack of liquid crystals.

### Exemplary Embodiment 2

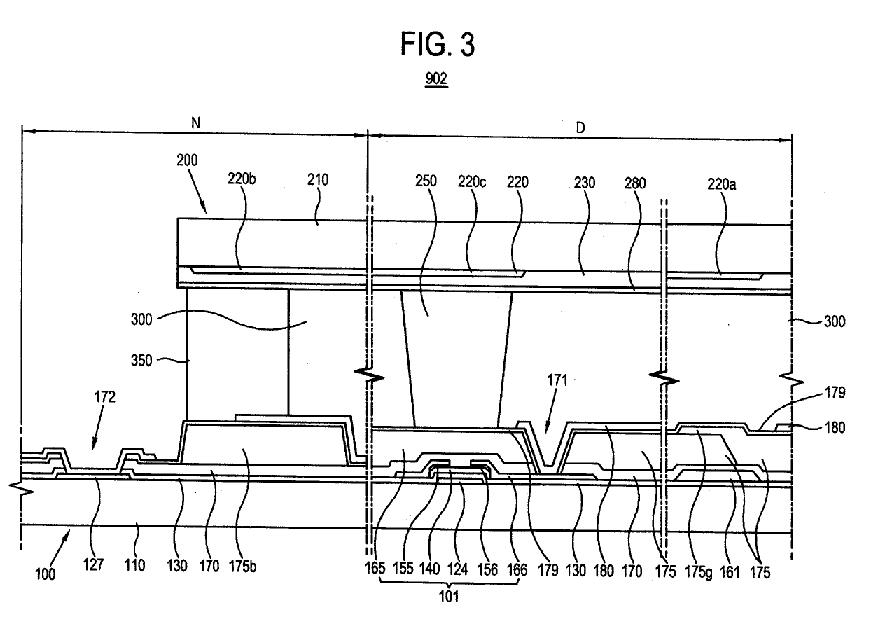

Referring to FIGS. 1 and 3, a display device according to a second exemplary embodiment of the present invention will be described. FIG. 3 is a sectional view of main parts of a display device 902 which is manufactured by a manufacturing method of the display device according to the second exemplary embodiment of the present invention.

As shown therein, the display device 902 includes a boundary part 175g of a first display panel 100 which is formed by overlapping color filters 175 having different colors and being adjacent to each other along boundaries between pixels. The boundary part 175g is not particularly thick compared to an adjacent color filter 175.

According to a manufacturing method of a display device, color filters 175 which include an overlapping part 175a (refer to FIG. 2) are formed in a plurality of pixel regions, and the overlapping part 175a of the color filters 175 is ground to form the boundary part 175g having a thinner thickness than that of the overlapping part 175a. Here, the overlapping part 175a refers to a part which is higher than adjacent elements and formed by overlapping the adjacent color filters 175 having different colors at the boundaries between the pixels.

The method of grinding the overlapping part 175a may include a known grinding method which is used to polish impurities created during a process of forming the color filters 175, and to reduce the thickness of the impurities.

A liquid crystal layer 300 is interposed between the first and second display panels 100 and 200. The minimum thickness of the liquid crystal layer 300 may be approximately 1 μm or more. That is, a minimum space between the first and second display panels 100 and 200 may be 1 μm or more.

With the foregoing method, the manufacturing method of the display device 902 according to the second exemplary embodiment of the present invention prevents errors such as a short-circuit or a lack of liquid crystals more stably.

### Exemplary Embodiment 3

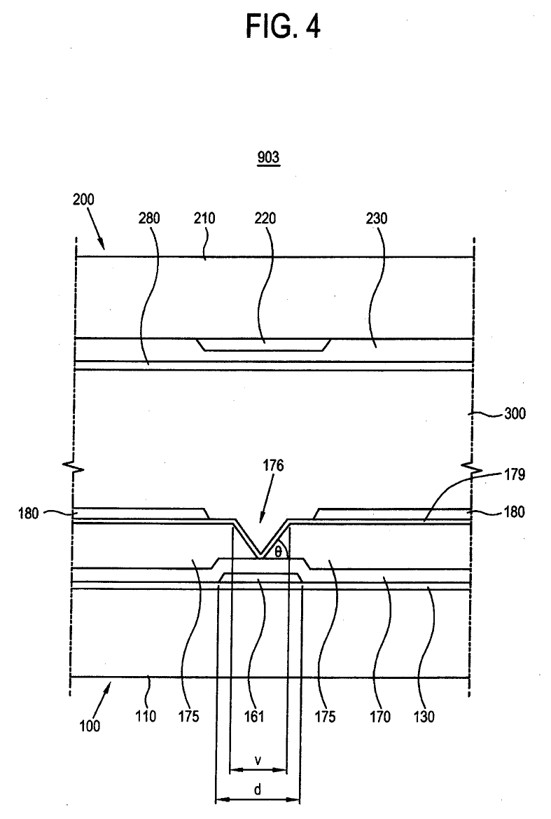

Referring to FIGS. 1 and 4, a display device according to a third exemplary embodiment of the present invention will be described. FIG. 4 is a partial sectional view of a display device 903 according to the third exemplary embodiment of the present invention, taken along line IV-IV in FIG. 1.

As shown therein, the display device 903 includes a groove 176 which is formed between color filters 175 having different colors and adjacent to each other at boundaries between pixels. Here, the groove 176 serves as a boundary between the adjacent color filters 175. The groove 176 is formed with an inclined lateral side of the color filters 175 adjacent to each other. The lower the color filters 175 are, i.e., the closer to the first substrate member 110 the color filters 175 are, the larger the color filters 175 are. Thus, a lateral side of the color filters 175 is inclined. That is, upper parts of the adjacent color filters 175 are spaced from each other. The lower the color filters 175 are, the narrower the space is between the color filters 175. A bottom of the color filter 175 may contact a bottom of an adjacent color filter 175. According to such a configuration, the groove 176 is formed between the adjacent color filters 175 having different colors. A metal wire (labeled 161) may be partly disposed below the groove 176. The metal wire (labeled 161) which is disposed below the groove 176 may represent a part of gate line 121 or data line 161. The metal wire (labeled 161) in FIG. 4 represents data line 161.

A width “v” of the groove 176 is narrower than a width “d” of the metal wire (labeled 161), and a pixel electrode 180 is formed on the color filters 175. Thus, light leakage which is likely to occur at boundaries between pixel regions, i.e., in the groove 176, may be stably prevented by the metal wire (labeled 161). The pixel electrode 180 is separated from an adjacent pixel electrode 180 by the groove 176 formed therebetween. That is, the pixel electrode 180 is spaced from the metal wire (labeled 161) as much as a thickness of the color filters 175. Thus, a coupling effect which may be created between the pixel electrode 180 and the metal wire 161 may be prevented.

An angle θ of lateral inclination of the groove 176 formed between the adjacent color filters 175 may be approximately 40° or more. The angle θ of lateral inclination refers to an inside angle θ of the lateral side of the color filters 175 with respect to a surface in parallel with a plate surface of the first substrate member 110. Thus, the width “v” of the groove 176 may be efficiently designed with respect to the metal wire (labeled 161) and the pixel electrode 180.

With the foregoing configuration, the display device 903 according to the third exemplary embodiment of the present invention may prevent errors such as a short-circuit or a lack of liquid crystals more stably (reliably).

### Exemplary Embodiment 4

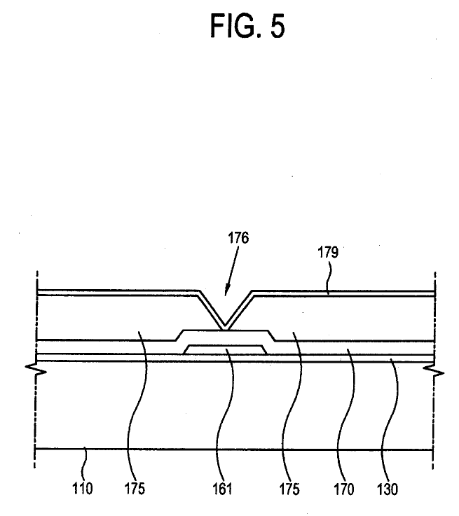

Referring to FIGS. 5 to 10, a manufacturing method of a display device according to a fourth exemplary embodiment of the present invention will be described. FIGS. 5 to 10 sequentially illustrate a manufacturing method of the display device in FIG. 3.

As shown in FIG. 5, color filters 175 which have the three primary colors are sequentially formed on a passivation layer 170 covering data wires 161, 165 and 166 (also shown in FIGS. 2 and 3). The color of the color filter 175 is not limited to the three primary colors, and may vary including at least one color.

The color filters 175 are formed in each pixel region. The color filters 175 are sequentially formed at boundaries between pixel regions having the color filters 175 of different colors and spaced from each other to form a groove 176 therebetween.

A capping layer 179 is formed on the color filters 175. The capping layer 179 protects organic layers, for example, including the color filters 175. According to an embodiment, the capping layer 179 can be omitted as necessary. The capping layer 179 may include various materials similar to that of the passivation layer 170.

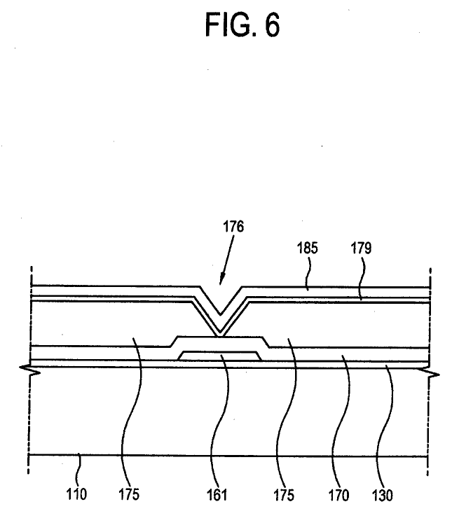

As shown in FIG. 6, a conductive layer 185 is formed on the capping layer 179. Here, the conductive layer 185 may include a transparent conductive material such as ITO or IZO.

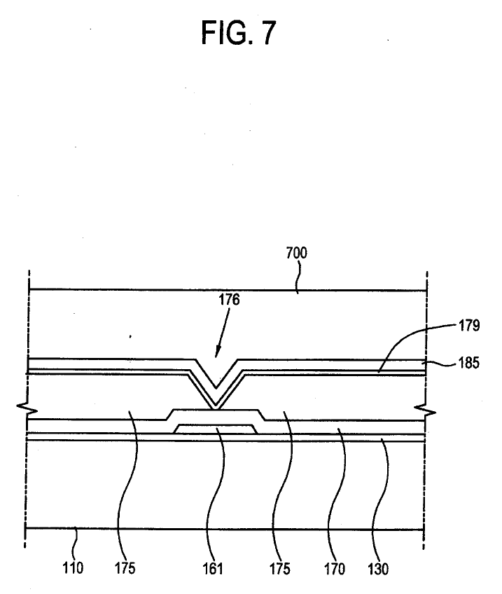

As shown in FIG. 7, a negative photoresist material 700 is applied to the conductive layer 175. The negative photoresist material 700 refers to a material of which a light-receiving portion remains in a developing process while other materials are removed in a developing process.

The negative photoresist material 700 according to the present invention may include various known negative photoresist materials determined easily by those skilled in the art.

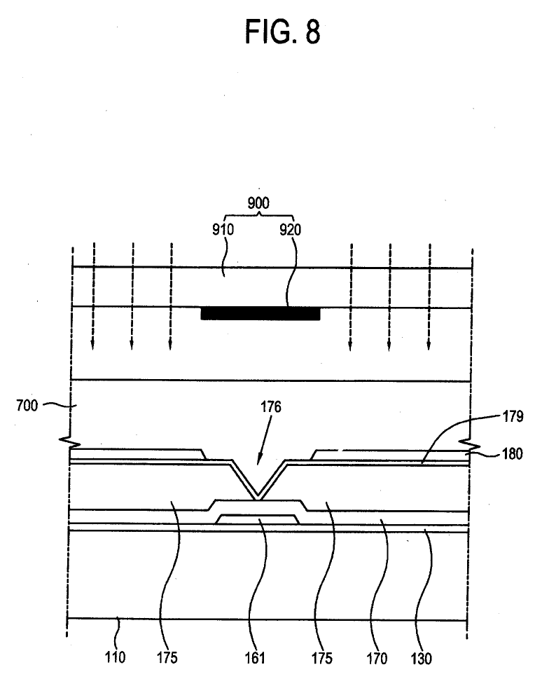

As shown in FIG. 8, the negative photoresist material 700 is exposed by a mask 900. The mask 900 includes a transparent substrate 910 and a light blocking pattern 920 formed on the transparent substrate 910. The mask 900 covers the negative photoresist material 700 disposed in the groove 176 between the adjacent color filters 175, so that it does not receive light.

Then, the exposed negative photoresist material 700 is baked. Alternatively, the baking process may be omitted depending on properties of a photoresist material used.

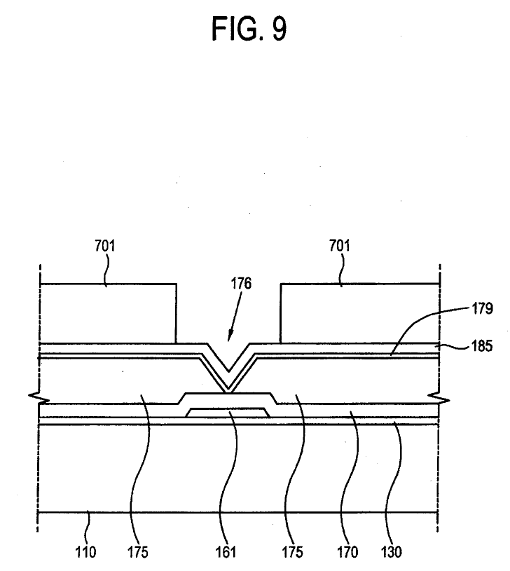

As shown in FIG. 9, the exposed, baked negative photoresist material 700 is developed to form a photoresist layer pattern 701. That is, the negative photoresist material 700 is removed from the groove 176 between the adjacent color filters 175 through the developing process to thereby form the photoresist layer pattern 701.

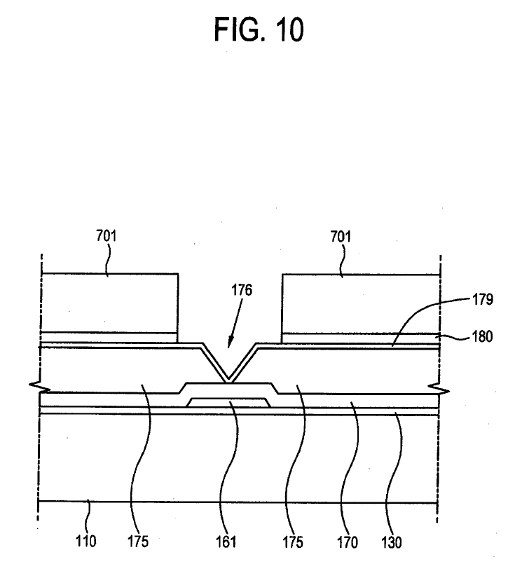

As shown in FIG. 10, the conductive layer 185 (shown in FIG. 9) is etched by the photoresist layer pattern 701 to thereby form a pixel electrode 180.

As described above, the conductive layer 185 is etched by a photolithography process to form the pixel electrodes 180 which are spaced from each other by the groove 176 of the adjacent color filters 175. The photolithography process includes a process of applying the negative photoresist material 700, a process of exposing and developing the negative photoresist material 700 to form the photoresist layer pattern 701 and a process of etching the conductive layer 185 using the photoresist layer pattern 701.

With the foregoing method, the manufacturing method of the display device according to the fourth exemplary embodiment of the present invention prevents errors such as a short-circuit or a lack of liquid crystals more stably.

### Exemplary Embodiment 5

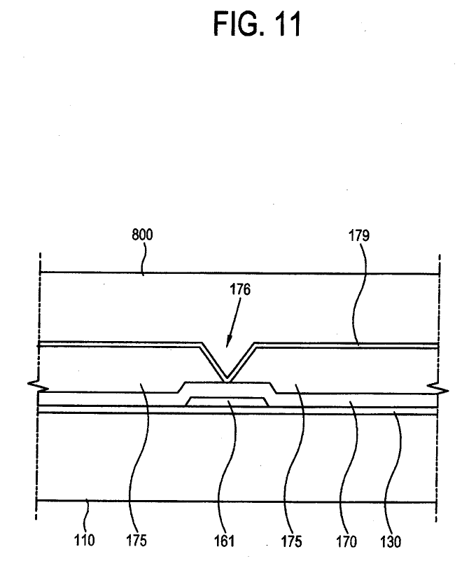

Referring to FIGS. 11 to 14, a manufacturing method of a display device according to a fifth exemplary embodiment of the present invention will be described. FIGS. 11 to 14 illustrate another manufacturing method of the display device in FIG. 3.

As shown in FIG. 11, color filters 175 are sequentially formed at boundaries between pixel regions having color filters 175 of different colors and spaced from each other to form a groove 176 therebetween.

A capping layer 179 is formed on the color filters 175. According to an embodiment, the capping layer 179 can be omitted as necessary.

A photoresist material 800 is applied to the capping layer 179. The photoresist material 800 may include a positive photoresist material and a negative photoresist material. A light blocking pattern 920 of a mask 900 which will be described later differs according to the type of the photoresist material 800. The photoresist material 800 in FIG. 11 includes the positive photoresist material. That is, a portion of the photoresist material 800 which does not receive light remains in a developing process while other materials are removed in a developing process.

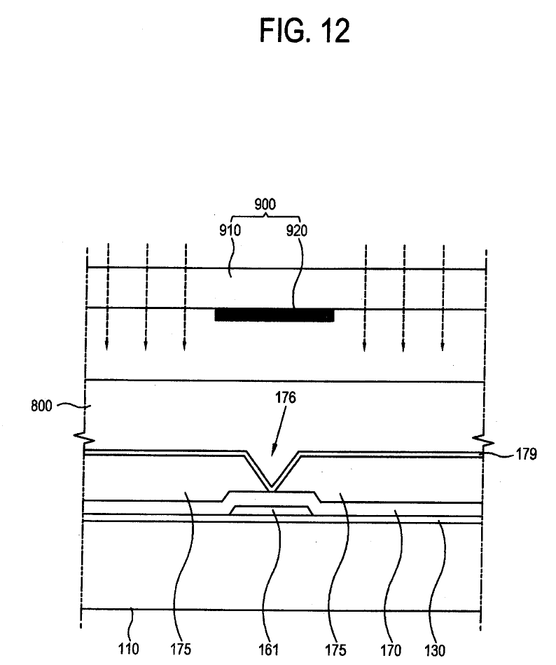

As shown in FIG. 12, the photoresist material 800 is exposed by the mask 900. The mask 900 includes a transparent substrate 910 and the light blocking pattern 920 formed on the transparent substrate 910. The mask 900 covers a photoresist material 700 disposed in the groove 176 between the adjacent color filters 175, so that it does not receive light.

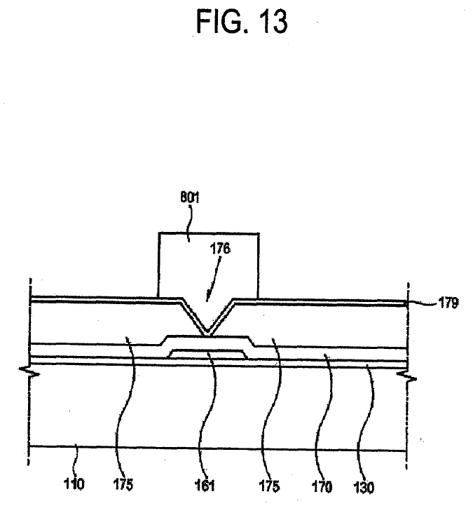

As shown in FIG. 13, the exposed photoresist material 800 (shown in FIG. 12) is developed to thereby form a photoresist layer pattern 801. That is, the photoresist material 800 is removed by the developing process, except the photoresist material 800 disposed in the groove 176 between the adjacent color filters 175 to form the photoresist layer pattern 801.

A photo-developing process refers to a process of applying, exposing and developing the photoresist material 800 to form the photoresist layer pattern 801.

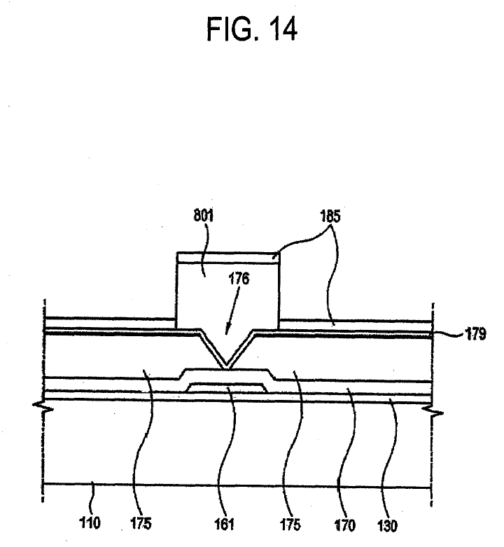

As shown in FIG. 14, a conductive layer 185 is formed on the photoresist layer pattern 801 and the color filters 175. The conductive layer 185 may include a transparent conductive material such as ITO or IZO to form a pixel electrode 180.

The photoresist layer pattern 801 is removed to form the pixel electrode 180 with the conductive layer 185. That is, the photoresist layer pattern 801 which is formed on the groove 176 between the adjacent color filters 175 is removed together with the conductive layer 185 formed on the photoresist layer pattern 801. Thus, the pixel electrodes 180 are spaced from each other by the groove 176 between the adjacent color filters 175.

With the foregoing method, the manufacturing method of the display device according to the fifth exemplary embodiment of the present invention prevents errors such as a short-circuit or a lack of liquid crystals more stably.

A manufacturing method of a display device according to embodiments of the present invention precisely forms a conductive layer pattern such as a pixel electrode on a color filter through an efficient and stable process and prevents errors such as a short-circuit or a lack of liquid crystals.

Furthermore, embodiments of the present invention may provide a display device which prevents errors such as a short-circuit or a lack of liquid crystals.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A manufacturing method of a display device, the manufacturing method comprising:
forming color filters in a plurality of pixel regions;
forming a conductive layer on the color filters; and
separating the conductive layer in each of the pixel regions through a photolithography process and forming a pixel electrode;
wherein a groove is formed between adjacent ones of the color filters having different colors at boundaries between the pixel regions; and
wherein the photolithography process uses a negative photoresist material.

2. The manufacturing method according to claim 1, wherein the photolithography process comprises:
applying a negative photoresist material to the conductive layer;
exposing the negative photoresist material with a mask;
forming a photoresist layer pattern by developing the exposed negative photoresist material; and
forming a pixel electrode by etching the conductive layer through the photoresist layer pattern;
wherein the negative photoresist material applied to the groove between the adjacent color filters is removed through the developing process.

3. The manufacturing method according to claim 2, further comprising forming a metal wire below the groove, wherein a width of the groove is narrower than a width of the metal wire.

4. A manufacturing method of a display device, the manufacturing method comprising:
forming color filters in a plurality of pixel regions;
forming a photoresist layer pattern on the color filters through a photo-developing process;
forming a conductive layer on the photoresist layer pattern; and
forming a pixel electrode with the conductive layer by removing the photoresist layer pattern;
wherein a groove is formed between adjacent ones of the color filters having different colors at boundaries between the pixel regions.

5. The manufacturing method according to claim 4, wherein the photo-developing process comprises:
applying a photoresist material to the color filters;
exposing the photoresist material with a mask; and
forming a photoresist layer pattern by developing the exposed photoresist material;
wherein the photoresist layer pattern comprises a photoresist layer formed on the groove between the adjacent color filters.

6. The manufacturing method according to claim 5, further comprising removing the conductive layer which is formed on the photoresist layer of the photoresist layer pattern together with the photoresist layer in the operation of removing the photoresist layer pattern.

7. The manufacturing method according to claim 4, wherein the photoresist material comprises one of a positive photoresist material and a negative photoresist material.

8. A display device which has a plurality of pixels and displays an image, the display device comprising:
a first substrate member;
a second substrate member which faces the first substrate member;
a color filter which is formed in each of the pixels on the first substrate member;
a metal wire which is disposed between the first substrate member and the color filter; and
a pixel electrode which is disposed between the color filter and the second substrate member;
wherein a groove is formed between adjacent ones of the color filters having different colors at boundaries between the pixels;
wherein a part of the metal wire is disposed below the groove between the adjacent color filters having different colors; and
wherein a width of the groove is narrower than a width of the metal wire.

9. The display device according to claim 8, wherein an angle of a lateral inclination of the groove formed between the adjacent color filters is approximately 40° or more.

10. A display device which is divided into a display region having a plurality of pixels and a non-display region surrounding the display region, the display device comprising:
a first substrate member;
a color filter which is formed in each of the pixels on the first substrate member;
a second substrate member which faces the first substrate member;
a light blocking member which is formed at boundaries between the pixels on a surface of the second substrate member facing the first substrate member; and
a liquid crystal layer which is interposed between the first substrate member and the second substrate member;
wherein adjacent ones of the color filters having different colors overlap each other at boundaries between the pixels to form an overlapping part which is relatively higher than other color filters; and
wherein the light blocking member corresponds to the overlapping part and has a thickness of approximately 0.7 μm or less.

11. The display device according to claim 10, wherein the color filters and the light blocking member are further formed on the non-display region and wherein the display device further comprises a sealant which is disposed along a circumference of the first and second substrate members in the non-display region.

12. The display device according to claim 11, wherein the color filter which is formed in the non-display region has a blue color.

13. The display device according to claim 10, further comprising a thin film transistor which is formed on the first substrate member, wherein
the light blocking member is further formed on a place corresponding to the thin film transistor; and
wherein the display device further comprises a substrate spacing member which is formed on the light blocking member and maintains a space between the first and second substrate members.

14. The display device according to claim 10, wherein a minimum thickness of the liquid crystal layer is approximately 1 μm or more.

15. A manufacturing method of a display device, the manufacturing method comprising:
forming a color filter which has an overlapping part in a plurality of pixel regions; and
forming a boundary part having a thinner thickness than that of the overlapping part by grinding the overlapping part of the color filters;
wherein the overlapping part is formed by overlapping adjacent ones of the color filters having different colors at boundaries between the pixel regions and is higher than other color filters.

16. The manufacturing method according to claim 15, wherein the color filters are formed on a first substrate member, wherein the manufacturing method further comprises:
disposing a second substrate member to face the first substrate member; and
interposing a liquid crystal layer between the first and second substrate members,
wherein a minimum thickness of the liquid crystal layer is approximately 1 μm or more.
